(19) United States
(12) Patent Application Publication
(10) Pub. No.: US 2005/0124119 A1
(43) Pub. Date: Jun. 9, 2005

(54) Open drain input/output structure and manufacturing method thereof in semiconductor device

(76) Inventors: Byung-Sup Shim, Seoul (KR); Young-Ho Kim, Yongin-city (KR)

Correspondence Address: MARGER JOHNSON & MCCOLLOM, P.C., 1030 SW MORRISON STREET, PORTLAND, OR, 97205, US

(21) Appl. No.: 11/039,970

(22) Filed: Jan. 20, 2005

Related U.S. Application Data
(62) Division of application No. 09/305,240, filed on May 4, 1999.

(30) Foreign Application Priority Data
May 4, 1998 (KR) 98-15975

(51) Int. Cl. H01L 21/8234

(52) U.S. Cl. 438/275

(57) ABSTRACT

The present invention relates to an open drain input/output structure and manufacturing method thereof in which a n-channel depletion transistor for pull-up resistance can be used like an enhancement transistor without impurity ion implantation process when being formed an open drain input/output terminal. An open drain input/output structure in a semiconductor device according to the present invention includes: a gate formed with an enhancement transistor at a predetermined portion on a first conductive-type semiconductor substrate which is formed with a gate insulating layer; a second conductive-type source/drain region formed in the semiconductor substrate at the both sides of the gate; and a second conductive-type impurity implantation region formed at a predetermined portion of a channel region at the lower part of the gate so as to selectively connected to the source region or the drain region. Therefore, according to the present invention, because the gate length of a n-channel depletion transistor is designed to have longer than conventional ones' so as to changed a depletion transistor into an enhancement transistor there is no necessary an impurity ion implantation process after gate forming process when an open drain I/O is achieved. Therefore, all a pull-up resistance I/O and an open drain I/O of a mask ROM embedded MCU, EPROM embedded MCU can be achieved with the same lay out structure thereby to be compatible when being manufactured MCU.

This application is a Divisional of U.S. Pat. No. 09/305,240, filed on May 4, 1999, now pending, which claims priority from Korean Patent Application No. 1998-15975, filed on May 4, 1998, both of which are hereby incorporated by reference in their entirety.

### BACKGROUND OF THE INVENTION

1. Field of the Invention

The present invention relates to a semiconductor device and manufacturing method thereof, and more particularly to an open drain input/output structure and manufacturing method thereof in which a n-channel depletion transistor for pull-up resistance can be used like an enhancement transistor without additional impurity ion implantation process when an open drain input/output terminal (referred to as I/O) is formed.

2. Description of the Prior Art In general, when an I/O of a MASKROM embedded MCU is realized, it is necessary to establish the same layout of an open drain option and a pull-up option.

Accordingly, when devices in the MASKROM embedded MCU are manufactured, two I/Os (open drain I/O and pull-up I/O) are realized in accordance with the followings. That is, pull-up I/O is first formed in such a manner that a contrary type of impurity to a substrate is ion-implanted into the channel region so that a gate is formed, and thereafter open drain I/O is formed in such a manner that a depletion transistor is converted into an enhancement transistor by further ion-implanting the same type of impurity as a substrate into only the channel region of cell which would be used as an open drain option during after gate programming (AGP) process.

The selective change of the depletion transistor into the enhancement transistor is for cutting off the depletion transistor for a pull-up resistance by the impurity ion implantation process because a current flow occurs through the pull-up resistance thereby causing an external component not to be controlled when the both terminals of the pull-up resistance of the pull-up resistance type I/O are applied with an electric voltage source of a chip and an external high voltage. Here, the open drain I/O controls components by using of an external high voltage.

That is, the depletion transistor is used as the pull-up resistance on the condition that the depletion transistor is changed into the enhancement transistor by the impurity ion implantation process for a channel region after being patterned a gate when the depletion transistor is intended to use as the open drain I/O.

FIG. 1 shows a circuit corresponding to a conventional open drain I/O structure.

Referring to FIG. 1, the two transistors which are connected to a first internal logic circuit 10a and a second internal logic circuit 10b, respectively, that is, a n-channel open drain transistor A and an enhancement transistor which is changed from the n-channel depletion transistor by the impurity ion implantation process, after the gate is formed, are connected in series each other. The two transistors are connected to an input/output pad 20. The pad 20 is connected with an external analog IC for applying an external high voltage unlike MOS-type LSI.

Reference numeral C represents a cutting-off point of the open drain circuit, D an open drain I/O input terminal, E an external component and Vdd an internal voltage.

Because the enhancement transistor B should keep in cut-off state, the first internal logic circuit 10a should be established to keep a low level signal. That is, when the second internal logic circuit 10b keeps a high level, an external signal is applied through the pad 20 and then a current flows the open drain transistor A so as to operate the external component.

FIG. 2 shows a conventional n-channel open drain transistor A structure, FIG. 3 shows an enhancement transistor B structure.

Referring to FIG. 2, a gate insulating layer 34 is formed on an active region of a first conductive type (for example, p-type) semiconductor substrate 30 which is formed with a field oxide film 32.

On the certain portion of the gate insulating layer 34 a gate having the accumulated layer of a W-silicide 36b and a polysilicon 36a is formed. On the both side walls of the gate 36, an insulative spacer 38 is formed. A second conductive type (for example, n-type) a source/drain region 42 provided with LDD (lightly doped drain) 40 is formed at the inside of the substrate 30.

In FIG. 2, reference numeral W1 represents the line width of the gate 36.

Referring to FIG. 3, an enhancement transistor B has a very similar structure with the n-channel open drain transistor A as shown in FIG. 2.

At the channel region of the lower part of a gate 36, a second conductive type (for example, n-type) impurity implantation region 44 is formed and a first conductive type (for example, p-type) impurity implantation region 46 is further formed at between region 44 so that a constant off state is kept except being provided with a high level signal.

In FIG. 3, reference numeral W2 represents the line width of the gate 36.

The enhancement transistor B is formed with being further ion-implanted a first-conductive type impurity to the channel region of a n-channel depletion transistor which is used as the pull-up resistance after the gate is formed.

FIG. 4 is a plane view of a layout structure after a gate is formed shown in FIG. 3.

In FIG. 4, a gate 36 is formed at a certain portion of a gate insulating layer 34 on a second conductive type impurity implantation region 44. A first conductive type impurity implantation region 46 is formed at between the second conductive type impurity implantation region 44 formed at the lower part of the gate 36.

The conventional method for forming the open drain I/O has the drawbacks as follows.

Firstly, when the n-channel depletion transistor is changed to the enhancement transistor so as to achieve the open drain I/O, the additional impurity ion implantation process must be performed one more time for forming the first conductive type impurity implantation region 46 after the gate is formed thereby causing not only the process to be complicated but also cost to be increased.

Secondly, when a system maker intends to achieve a EPROM embedded MCU by using a non-volatile memory for example EPROM on the purpose of developing a program and of applying to the market, there is no problem to achieve the open drain I/O by the process and the layout different from a conventional mask ROM embedded MCU. However, there is a problem for the open/drain I/O to achieve by using the same layout as the conventional layout. That is, because an AGP (after gate programming) coding is not used for the EPROM embedded MCU, it is not necessary the impurity ion implantation process after the gate is formed. Therefore, it is not possible to achieve selectively between the I/O for the pull-up resistance of the EPROM embedded MCU and the open drain I/O. That is, it is possible for the mask ROM embedded MCU to achieve the open drain I/O and the I/O for pull-up resistance, but it is possible for the EPROM embedded MCU to achieve only the I/O for pull-up resistance.

Therefore, it is required for the open drain I/O having the same layout to apply in the mask ROM embedded MCU and the EPROM embedded MCU.

### SUMMARY OF THE INVENTION

Therefore, the present invention has been invented to overcome the conventional drawbacks, it is an object of the present invention to provide an open drain input/output structure in a semiconductor device and manufacturing method thereof in a semiconductor device in which an open drain I/O can be achieved to apply to a mask ROM embedded MCU and to an EPROM embedded MCU without an additional process (for example, an impurity ion implantation process) by forming the gate line width of an enhancement transistor connected to an input/output pad so as to have wider size than the impurity-implanted region being formed in the channel region.

Another object of the present invention is to provide an open drain input/output manufacturing method which enables to effectively achieve an open drain structure of the input/output.

In order to achieve the above object, first to second embodiments of the present invention provide an open drain I/O structure of a semiconductor device including an enhancement transistor having the channel region and an open drain transistor having the channel region, wherein gates for forming the open drain transistor are formed so as to have the same line width as the length of an impurity implantation region formed in the channel region, and gates for forming the enhancement transistor are formed so as to have a wider line width than the length of an impurity implantation region formed in the channel region.

At this time, the impurity implantation region formed in the channel region of the enhancement transistor can be formed to be connected to and united to a selected one of source and drain regions forming the enhancement transistor, or, can be formed at the center portion of the channel region to be separated at a predetermined distance from the source and drain regions forming the enhancement transistor.

In order to achieve the another object, according to first and second embodiments of the present invention, a method of manufacturing I/O of a semiconductor device including an enhancement transistor having a channel region and an open drain transistor having a channel region, wherein the method of manufacturing the enhancement transistor comprises the steps of: forming a gate insulating layer in the active region on a first conductive-type semiconductor substrate, forming an impurity implantation region at a predetermined portion within the substrate of the lower side of the gate insulating layer through ion implantation of a second conductive-type impurity of low concentration, forming a gate on the gate insulating layer by forming conductive layer on the whole surface of the product and selectively-etching it so that a predetermined portion of the impurity implantation region and a predetermined portion of the substrate surface being close to the region being connected to the predetermined portion of the impurity implantation region are included at a predetermined portion, and forming source and drain regions within the substrate at both edges of the gate through ion-implantation process of second conductive type of high concentration impurity.

In order to achieve the other object, according to third embodiment of the present invention, a method of manufacturing I/O of a semiconductor device including an enhancement transistor having a channel region and an open drain transistor having a channel region, wherein the method of manufacturing the enhancement transistor comprises the steps of: forming a gate insulating layer in the active region on a first conductive-type semiconductor substrate, forming an impurity implantation region at a predetermined portion within the substrate of the lower side of the gate insulating layer through ion implantation of a second conductive-type impurity of low concentration, forming a gate on the gate insulating layer by forming conductive layer on the whole surface of the product and selectively-etching it so that the impurity implantation region and the substrate surface therearound are included at a predetermined portion, and forming source and drain regions within the substrate at both edges of the gate through ion-implantation process of second conductive type of high concentration impurity.

In case of manufacturing the open drain I/O of the semiconductor device to have the above-mentioned structure, when the gate size at the open drain I/O-formed portion is simply allowed to be a little longer than that of a conventional art, the n channel depletion transistor can be accordingly enhancement-transistorized, so it is not necessary to prepare a separate impurity ion-implantation process for realizing the open drain I/O after formation of a gate. As a result, using the open drain I/O as mentioned above enables realizing of MASKROM embedded MCU, I/O for pull-up resistance of EPROM embedded MCU, and open drain I/O.

### BRIEF DESCRIPTION OF THE DRAWINGS

The above object, and other features and advantages of the present invention will become apparent after a reading of the following detailed description when taken in conjunction with the drawings, in which:

FIG. 1 is a schematic circuit diagram illustrating an open drain input/output stage structure of a conventional semiconductor device;

FIG. 2 is a sectional view for the open drain transistor A in FIG. 1;

FIG. 3 is a sectional view for the enhancement transistor B in FIG. 1;

FIG. 4 is a plane view illustrating the layout structure after the gate is formed in FIG. 3;

FIG. 5a to FIG. 5c are views illustrating an input/output stage structure of the semiconductor device according to the first embodiment of the present invention,

FIG. 5a is a sectional view illustrating the enhancement transistor structure of the open drain input/output stage;

FIG. 5b is a plane view illustrating the layout structure after the gate is formed;

FIG. 5c is an equivalent circuit of FIG. 5a;

FIG. 6a to FIG. 6c are views illustrating an input/output stage structure of the semiconductor device according to the second embodiment of the present invention,

FIG. 6a is a sectional view illustrating the enhancement transistor structure of the open drain input/output stage;

FIG. 6b is a plane view illustrating the layout structure after being formed the gate;

FIG. 6c is an equivalent circuit of FIG. 6a;

FIG. 7a to FIG. 7c are views illustrating an input/output stage structure of the semiconductor device according to the third embodiment of the present invention,

FIG. 7a is a sectional view illustrating the enhancement transistor structure of the open drain input/output stage;

FIG. 7b is a plane view illustrating the layout structure after being formed the gate; and

FIG. 7c is an equivalent circuit of FIG. 7a.

### DETAILED DESCRIPTION OF THE PREFERRED EMBODIMENTS

Embodiment 1

The feature of the present invention is that the n-channel depletion transistor is simply enhancement-transistorized without the ion-implantation process performing after formation of a gate through variation of the gate line width at the open drain I/O-formed portion.

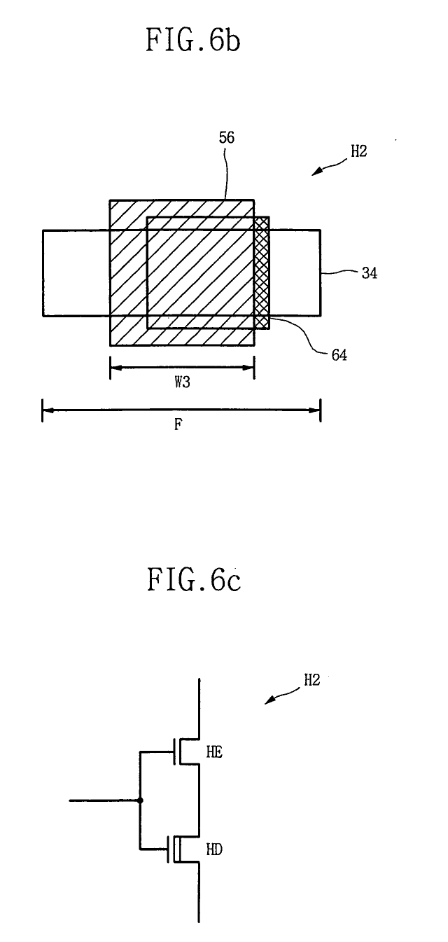

FIG. 5a is a sectional view of an open drain I/O enhancement transistor structure according to the present invention, FIG. 5b is a plane view of the layout structure after a gate is formed in FIG. 5a, and FIG. 5c is an equivalent circuit diagram of FIG. 5a.

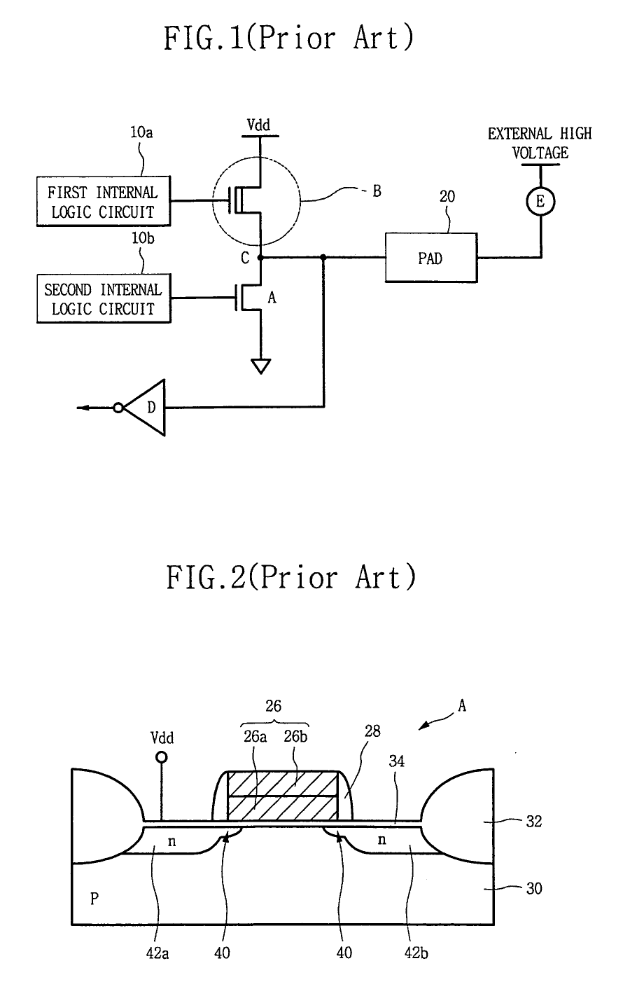

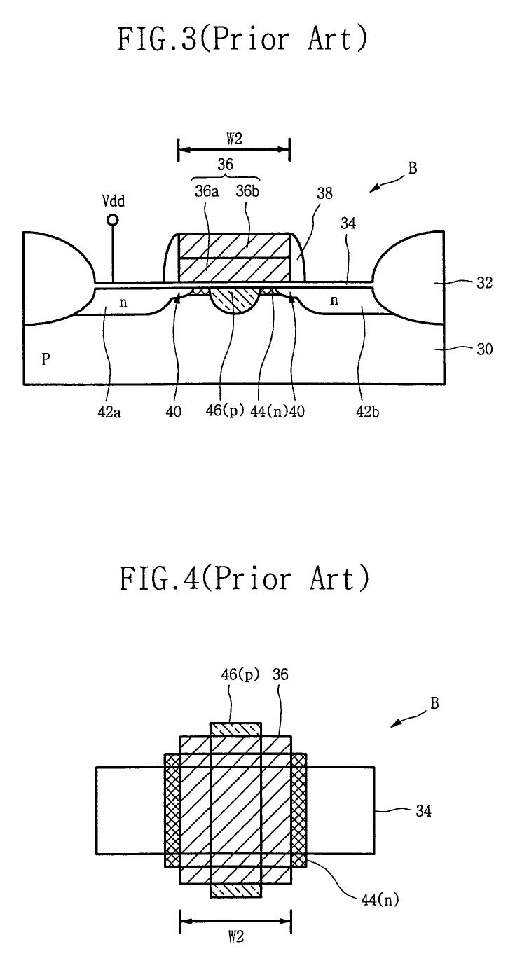

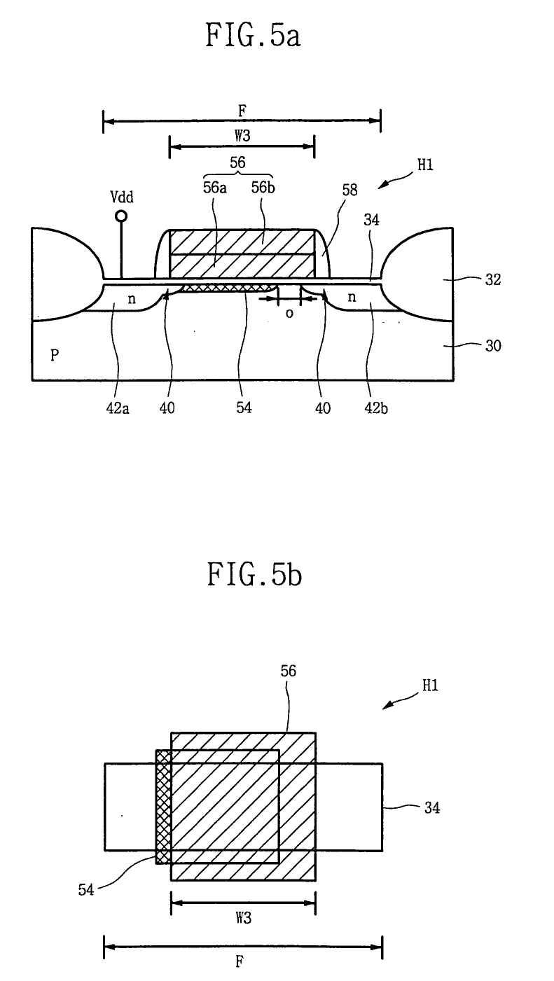

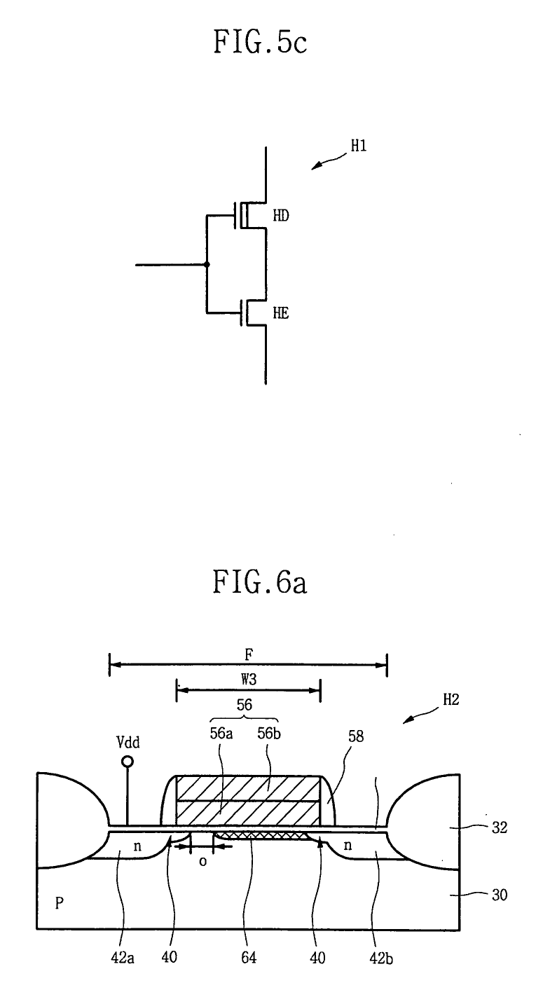

There is omitted the descriptions for a n-channel open drain transistor except the manufacturing method of an enhancement transistor B represented in the part I in FIG. 1.

As shown in FIG. 5a, a gate insulating layer 34 is formed at an active region F on a first conductive type (for example, p-type) semiconductor substrate 30 formed with a field oxide layer 32. On the partial portion of the gate insulating layer 34, a gate is formed to be accumulated by a polysilicon 36a and a W-silicide 36b in order thereof (or one step structure of a polysilicon). Both sides of wall are formed with an insulating spacer 38.

On certain portions in the substrate 30, a second conductive type (for example, n-type) of source and drain regions 42a and 42b formed with a LDD 40.

At the channel region formed at the lower part of the gate 34, a second conductive type (for example, n-type) impurity implantation region 44 is formed to be coupled to a source region but to be maintained by a predetermined distance from a drain region. Where W3 indicates the line width of a gate.

The enhancement transistor having the above-structure is manufactured through the following four steps.

At first step, the gate insulating layer 34 is formed at the active region F on the first conductive type semiconductor substrate 30 which is formed with the field oxide layer 32 and the second conductive type impurity is selectively implanted on the partial portion of the gate insulating layer 34 so that the second conductive type impurity implartation region 44 is formed at the certain portions in the substrate 30.

At second step, the gate 36 is formed on the gate insulating layer 34 so as to be included a certain portion of the impurity implantation region 44 and a certain portion of the surface of the substrate 30 connected thereto.

For convenience sake, the gate 36 is shown to be accumulated by the polysilicon 36a and the W-silicide 36b (W-silicide/ polysilicon) in order thereof, but there is no problem to be one step structure by the polysilicon as circumstances may require.

Because the second conductive type impurity implantation region 44 should be formed only at the certain portions of the channel region in order to achieve the open drain structure without the first conductive type impurity ion implantation process for opening the channel, the gate 36 should be formed to have a little longer length W3 than the conventional length. It can be understood with reference to FIG. 5b.

At third step, the second conductive type impurity in low concentration is ion-implanted to the substrate 30 through the gate 36 as a mask so as to be formed LDD 40 in the substrate 30 at both sides of the gate 36.

At fourth step, the insulating spacer 38 is formed at both side walls of the gate 36 and the second conductive type impurity in high concentration is ion-implanted to the substrate 30 through the spacer 38 as a mask so as to be formed the source/drain regions 42a and 42b in the substrate 30.

FIG. 5c shows a portion differing from the conventional technique for the part I as shown in FIG. 1.

The transistor operates as the depletion transistor B2 at the n-channel region which is formed with the second conductive type impurity implantation region 44, whereas operates as the enhancement transistor B1 at the p-channel region (portion “O” in drawing) which is not formed with the impurity implantation region 44 so that the enhancement transistor can be cut-off only when the voltage Vdd is applied to the source region thereby to be applied a low level signal to the gate.

Embodiment 2

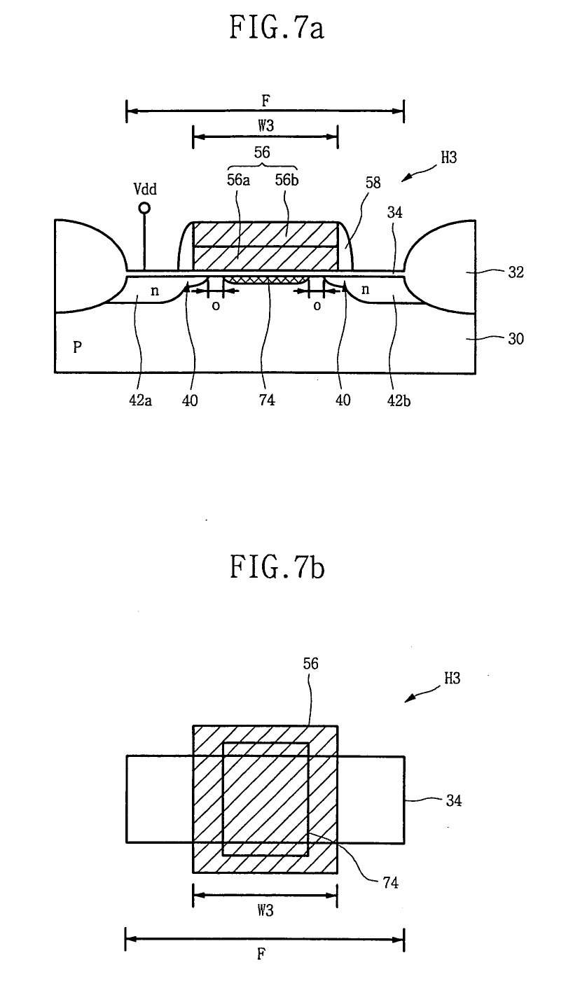

FIG. 6a is a cross-sectional view of an open drain I/O enhancement transistor structure according to the present invention, FIG. 6b is a plane view of the lay out structure after a gate forming process in FIG. 6a, and FIG. 6c is an equivalent circuit diagram of FIG. 6a.

As shown in FIG. 6a, a gate insulating layer 34 is formed at the active region F on a first conductive type (for example, p-type) semiconductor substrate 30 formed with a field oxide layer 32.

On the partial portion of the gate insulating layer 34, a gate is formed to be accumulated a polysilicon 36a and a W-silicide 36b in order (or one step structure of a polysilicon). Both side walls are formed with an insulating spacer 38. On the certain portions in the substrate 30, a second conductive type (for example, n-type) source/drain regions 42a, 42b which is formed with a LDD 40 is formed.

At the channel region formed with the lower part of the gate 34, a second conductive type (for example, n-type) impurity implantation region 44 is formed to be coupled to a drain region but to be maintained by a predetermined distance from a source region.

In FIG. 6a, reference numeral W represents he length of the gate 34.

As shown in FIG. 6b, the second embodiment is different from the first embodiment only with respect to the position to be formed the gate 36. Therefore, it is omitted the descriptions about the manufacturing process.

FIG. 6c shows an equivalent circuit for a transistor in FIG. 6a.

Referring to FIG. 6c, the transistor operates as the enhancement transistor B1 at the p-channel region (part “o” in the drawing) which is not formed with the second-type impurity implantation region 44, whereas, operates as the depletion transistor B2 at the n-channel region which is formed with the impurity implantation region so that the enhancement transistor can be cut-off when the gate is provided with a low level with being applied the voltage Vdd to the source region.

Embodiment 3

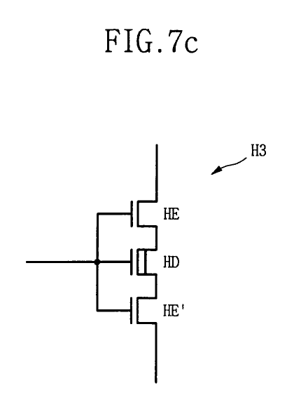

The third embodiment will now be described with reference to FIGS. 7a, 7b and 7c.

As shown in FIG. 7a, a gate insulating layer 34 is formed at the active region F on a first conductive type (for example, p-type) semiconductor substrate 30 formed with a field oxide layer 32.

On the partial portion of the gate insulating layer 34, a gate is formed to be accumulated a polysilicon 36a and a W-silicide 36b in order (or one step structure of a polysilicon). Both side walls are formed with an insulating spacer 38.

On the certain portions in the substrate 30, a second conductive type (for example, n-type) source/drain region 42 formed with a LDD 40 is formed.

At the channel region formed at the lower part of the gate 34, a second conductive type (for example, n-type) impurity implantation region 44 is formed to be maintained by a predetermined distance from a source/drain regions 42a, 42b.

The enhancement transistor having the above-structure is manufactured through the following four steps.

At first step, the gate insulating layer 34 is formed at the active region F on the first conductive type semiconductor substrate 30 which is formed with the field oxide layer 32 and the second conductive type impurity is selectively implanted on the partial portion of the gate insulating layer 34 so that the second conductive type impurity implantation region 44 is formed at the certain portions in the substrate 30.

At second step, the gate 36 is formed on the gate insulating layer 34 so as to be included a certain portion of the impurity implantation region 44 and a certain portion of the surface of the substrate 30 connected thereto.

In this case, the gate 36 is formed to be accumulated the polysilicon 36a and the W-silicide 36b in order or one step structure of the polysilicon. It can be understood with reference to FIG. 7b.

At third step, the second conductive type impurity in low concentration is ion-implanted to the substrate 30 through the gate 36 as a mask so as to be formed LDD 40 in the substrate 30 at both sides of the gate 36.

At fourth step, the insulating spacer 38 is formed at both side walls of the gate 36 and the second conductive type impurity in high concentration is ion-implanted to the substrate 30 through the spacer 38 as a mask so as to be formed the source/drain regions 42a and 42b in the substrate 30.

FIG. 7c shows an equivalent circuit for the transistor in FIG. 7a.

Referring to FIG. 7c, it is sure that the p-channel (part “o” in the drawing) is formed at the both sides of the n-channel region as the impurity implantation region 44. The transistor having the above structure operates at the p-channel region as the enhancement transistor B1 and operates at the n-channel region as the depletion transistor B2.

Therefore, B1 and B1′ transistors can be cut off only when the gate is applied with a low level signal with the voltage Vdd being applied to the source region.

While a specific embodiment of the present invention has been disclosed in the drawings and specification, these embodiments are used in a generic and descriptive sense only and not for purposes of limitation, the scope of the invention being set forth in the following claims.

As the above detailed descriptions, according to the present invention, because a gate length of a n-channel depletion transistor is designed to have longer than conventional ones' so as to change a depletion transistor into an enhancement transistor there is no necessary an impurity ion implantation process after gate forming process when an open drain I/O is achieved. Therefore, all a pull-up resistance I/O and an open drain I/O of a mask ROM embedded MCU, EPROM embedded MCU can be achieved with the same lay out structure thereby to be compatible when being manufactured MCU.

1. A method of manufacturing input and output terminal of a semiconductor device including an enhancement transistor having a channel region and an open drain transistor having a channel region, wherein the method of manufacturing the enhancement transistor comprises the steps of:
forming a gate insulating layer in an active region on a first conductive-type semiconductor substrate,
forming an impurity implantation region at a predetermined portion within the substrate of the lower side of the gate insulating layer through ion implantation of a second conductive-type impurity of low concentration,
forming a gate on the gate insulating layer by forming conductive layer on the whole surface of the resulting product and selectively-etching it so that a predetermined portion of the impurity implantation region and a predetermined portion of the substrate surface being close to the region being connected to the predetermined portion of the impurity implantation region are included at a predetermined portion, and
forming source and drain regions within the substrate at both edges of the gate through ion-implantation process of second conductive type of high concentration impurity.

2. The method of manufacturing input and output terminal of a semiconductor device as defined in claim 1, wherein the gate has a deposition layer such as “W-silicide/polysilicon”, or a single layer of polysilicon.

3. A method of manufacturing input and output terminal of a semiconductor device including an enhancement transistor having a channel region and an open drain transistor having a channel region, wherein the method of manufacturing the enhancement transistor comprises the steps of:
forming a gate insulating layer in an active region on a first conductive-type semiconductor substrate,
forming an impurity implantation region at a predetermined portion within the substrate of the lower side of the gate insulating layer through ion implantation of a second conductive-type impurity of low concentration,
forming a gate on the gate insulating layer by forming conductive layer on the whole surface of the product and selectively-etching it so that the impurity implantation region and the substrate surface therearound are included at a predetermined portion, and
forming source and drain regions within the substrate at both edges of the gate through ion-implantation process of second conductive type of high concentration impurity.

4. The method of manufacturing input and output terminal of a semiconductor device as defined claim 3, wherein the gate has a deposition layer such as “W-silicide/polysilicon”, or a single layer of polysilicon.

5. The method of manufacturing input and output terminal of a semiconductor device as defined in claim 1, wherein the source region and drain region define between them a channel region, and one of the source region and the drain region is electrically coupled to an I/O pad, and the other one of the source region and the drain region is electrically coupled to a Vdd terminal.

6. The method of manufacturing input and output terminal of a semiconductor device as defined in claim 1, wherein the impurity implantation region is formed in the channel region and separated from one of the drain region and source region.

7. The method of manufacturing input and output terminal of a semiconductor device as defined in claim 1, wherein the impurity implantation region comprises a depletion channel of the second conductivity type.

8. The method of manufacturing input and output terminal of a semiconductor device as defined in claim 1, wherein the impurity implantation region includes a first surface of the semiconductor substrate, wherein a width of the first surface is equal to a width of the impurity implantation region.

9. The method of manufacturing input and output terminal of a semiconductor device as defined in claim 1, wherein a region between the impurity implantation region of a second conductivity type and the drain region is formed with an enhancement channel of the first conductivity type with uniform doping concentration and occupying a second surface of the semiconductor substrate.

10. The method of manufacturing input and output terminal of a semiconductor device as defined in claim 1, wherein the gate is formed on the gate insulating layer over at least a portion of the depletion channel and over at least a portion of the enhancement channel, wherein the gate has a narrowest width that is greater than a width of the impurity implantation region.

11. The method of manufacturing input and output terminal of a semiconductor device as defined in claim 1, wherein the impurity implantation region has a narrower width than a width of the gate.

12. The method of manufacturing input and output terminal of a semiconductor device as defined in claim 1, wherein the gate comprises a first portion over the enhancement channel and a second portion over the depletion channel and the first portion is in a predetermined ratio with respect to the second portion.

13. The method of manufacturing input and output terminal of a semiconductor device as defined in claim 3, wherein the source region and drain region define between them a channel region, and one of the source region and the drain region is electrically coupled to an I/O pad, and the other one of the source region and the drain region is electrically coupled to a Vdd terminal.

14. The method of manufacturing input and output terminal of a semiconductor device as defined in claim 3, wherein the impurity implantation region is formed in the channel region and separated from the drain region and source region by a predetermined distance.

15. The method of manufacturing input and output terminal of a semiconductor device as defined in claim 3, wherein the impurity implantation region comprises a depletion channel of the second conductivity type.

16. The method of manufacturing input and output terminal of a semiconductor device as defined in claim 3, wherein the impurity implantation region includes a first surface of the semiconductor substrate, wherein a width of the first surface is equal to a width of the impurity implantation region.

17. The method of manufacturing input and output terminal of a semiconductor device as defined in claim 3, wherein a region between the impurity implantation region of a second conductivity type and the drain region is formed with an enhancement channel of the first conductivity type with uniform doping concentration and occupying a second surface of the semiconductor substrate.

18. The method of manufacturing input and output terminal of a semiconductor device as defined in claim 3, wherein the gate is formed on the gate insulating layer over at least a portion of the depletion channel and over at least a portion of the enhancement channel, wherein the gate has a narrowest width that is greater than a width of the impurity implantation region.

19. The method of manufacturing input and output terminal of a semiconductor device as defined in claim 3, wherein the impurity implantation region has a narrower width than a width of the gate.

20. The method of manufacturing input and output terminal of a semiconductor device as defined in claim 3, wherein the gate comprises a first portion over the enhancement channel and a second portion over the depletion channel and the first portion is in a predetermined ratio with respect to the second portion.
